(19) United States
(12) Patent Application Publication
(10) Pub. No.: US 2024/0172486 A1
(43) Pub. Date: May 23, 2024

(54) ORGANIC LIGHT-EMITTING DISPLAY DEVICE

(71) Applicant: LG Display Co., Ltd., Seoul (KR)

(72) Inventors: Daehee KIM, Goyang-si (KR); MoonSoo KIM, Paju-si (KR)

(21) Appl. No.: 18/509,225

(22) Filed: Nov. 14, 2023

(30) Foreign Application Priority Data
Nov. 22, 2022 (KR) 10-2022-0156931

(51) Int. Cl. H10K 59/122; H10K 59/12; H10K 59/80

(52) U.S. Cl. CPC H10K 59/122; H10K 59/1201; H10K 59/80521

(57) ABSTRACT

An organic light-emitting display device includes a first anode electrode disposed in a first sub-pixel; a second anode electrode disposed in a second sub-pixel; a third anode electrode disposed in a third sub-pixel; at least one ground electrode disposed in the third sub-pixel and spaced apart from the third anode electrode; a first organic light-emitting layer, a first cathode electrode, a first portion of a second organic light-emitting layer, and a first portion of a second cathode electrode sequentially stacked on the first anode electrode and the second anode electrode; and a second portion of the second organic light-emitting layer and a second portion of the second cathode electrode sequentially stacked on the third anode electrode, wherein at least a portion of a side edge of the second portion of the second cathode electrode contacts the at least one ground electrode.

### CROSS-REFERENCE TO RELATED APPLICATION

This application claims priority from Korean Patent Application No. 10-2022-0156931 filed on Nov. 22, 2022 in the Korean Intellectual Property Office, and all the benefits accruing therefrom under 35 U.S.C. § 119, the contents of which in its entirety are herein incorporated by reference.

### BACKGROUND

### Technical Field

The present disclosure relates to an organic light-emitting display device, and more particularly, to an organic light-emitting display device in which luminance of a blue sub-pixel may be improved, and lifetime thereof may be increased.

### Description of Related Art

As society enters the age of information, various display devices that process and display a large amount of information have been developed. There are various types of display devices such as liquid crystal display device (LCD), an organic light-emitting display device (OLED), and a quantum dot display device (QD) based on a light-emitting principle.

The organic light-emitting display device (OLED) is a self-luminous display device. Thus, unlike the liquid crystal display device (LCD), the OLED does not include a separate light source, and thus can be manufactured in a lightweight and thin manner. Further, the OLED is not only advantageous in terms of power consumption due to low operation voltage thereof, but also has excellent advantages in color rendering, response speed, viewing angle, and contrast ratio (CR).

The organic light-emitting display device can employ a variety of schemes for the formation of a pixel. A possible scheme is one in which an organic light-emitting element that emits red light is disposed in a red sub-pixel, an organic light-emitting element that emits blue light is disposed in a blue sub-pixel, and an organic light-emitting element that emits green light is disposed in a green sub-pixel. Another possible scheme is one in which an organic light-emitting element emitting white light is disposed in each of all sub-pixels, and red, green, and blue color filters are respectively disposed in red, green, and blue sub-pixels. Various other schemes have been proposed, some of which have increased difficulty in terms of a manufacturing process and others of which have advantages thereof in terms of productivity and high-resolution implementation.

### BRIEF SUMMARY

In the organic light-emitting display device employing the scheme in which an organic light-emitting element emitting white light is disposed in each of all sub-pixels, and red, green, and blue color filters are respectively disposed in red, green, and blue sub-pixels, the white light emitted from the white organic light-emitting element travels through the red color filter, the green color filter, and the blue color filter to render red, green and blue colors, respectively.

However, as the white light travels through the color filters, luminance of the light exiting the color filters is reduced due to light absorption by the color filters. In particular, as the white light travels through the blue color filter, the luminance of the blue light exiting the blue color filter is greatly reduced.

The organic light-emitting element emitting the white light generally includes a blue light-emitting layer. Also in the blue sub-pixel area, the blue light-emitting layer and light-emitting layers emitting light of different colors from the blue color are disposed to emit the white light, and the white light mixed with lights emitted from these light emitting layers is passed through the blue color filter to obtain the blue color. However, not only light-emitting efficiency of the blue light-emitting layer itself is lowered, but also the luminance of the blue light exiting the blue color filter is further reduced due to light absorption by the color filter.

In the organic light-emitting display device employing the scheme in which the organic light-emitting element emitting white light is disposed in each of all sub-pixels, and red, green, and blue color filters are respectively disposed in red, green, and blue sub-pixels, lateral leakage current is generated through a common layer with high conductivity at a low gray level, thereby unintentionally causing an adjacent sub-pixel to emit light.

Further, the organic light-emitting element includes an organic material that may be easily deteriorated by moisture, etc. Thus, a lifetime of the organic light-emitting element is shortened because the organic light-emitting element is deteriorated by the moisture introduced from an outside.

A technical purpose according to an embodiment of the present disclosure is to provide an organic light-emitting display device capable of improving luminance of blue light.

Further, a technical purpose according to an embodiment of the present disclosure is to provide an organic light-emitting display device capable of reducing lateral leakage current.

Further, a technical purpose according to an embodiment of the present disclosure is to provide an organic light-emitting display device capable of preventing external moisture from invading an organic light-emitting element.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

An organic light-emitting display device according to one embodiment of the present disclosure includes a first anode electrode disposed in a first sub-pixel; a second anode electrode disposed in a second sub-pixel; a third anode electrode disposed in a third sub-pixel; at least one ground electrode disposed in the third sub-pixel and spaced apart from the third anode electrode; a first organic light-emitting layer, a first cathode electrode, a first portion of a second organic light-emitting layer, and a first portion of a second cathode electrode sequentially stacked on the first anode electrode and the second anode electrode; and a second portion of the second organic light-emitting layer and a second portion of the second cathode electrode sequentially stacked on the third anode electrode, wherein at least a portion of a side edge of the second portion of the second cathode electrode contacts the at least one ground electrode.

An organic light-emitting display device according to one embodiment of the present disclosure includes an anode electrode disposed in a sub-pixel; at least one ground electrode disposed in the sub-pixel and spaced apart from the anode electrode; an organic light-emitting layer and a cathode electrode sequentially stacked on the anode electrode; and a wall structure adjacent to side edges of the cathode electrode and spaced apart from the side edges of the cathode electrode, wherein the wall structure includes a portion of the organic light-emitting layer and a portion of the cathode electrode, wherein at least a portion of side edges of the cathode electrode disposed on the anode electrode contacts the at least one ground electrode.

A method according to one embodiment of the present disclosure includes: forming an anode electrode and a ground electrode on a substrate, the ground electrode being spaced apart from the anode electrode; forming a bank that exposes a first surface of the anode electrode and a second surface of the ground electrode; forming a shield layer that covers the anode electrode and the ground electrode; forming a first light-emitting layer on the shield layer, the first light-emitting layer having a first portion on a sidewall of the shield layer; forming a first cathode electrode layer on the first light-emitting layer, the first cathode electrode layer having a second portion on the sidewall of the shield layer; forming a wall structure by removing the shield layer, the wall structure including the first portion and the second portion, the first surface and the second surface being exposed following the removing the shield layer; forming a second light-emitting layer on the first surface and the wall structure, the second light-emitting layer being discontinuous between the first surface and the wall structure; and forming a second cathode electrode layer on the second light-emitting layer, the second cathode electrode layer being discontinuous between the first surface and the wall structure, the second cathode electrode layer having at least one edge that is in contact with the second surface of the ground electrode.

Details of the other embodiments are included in the detailed description and drawings.

According to the embodiments of the present disclosure, the organic light-emitting display device capable of improving the luminance of the blue light may be provided.

Further, according to the embodiments of the present disclosure, the organic light-emitting display device capable of preventing external moisture from invading the organic light-emitting element may be provided. In particular, the organic light-emitting display device capable of preventing external moisture from invading the blue organic light-emitting element may be provided.

Therefore, according to the embodiments of the present disclosure, the organic light-emitting display device having the increased lifespan may be provided. In particular, the organic light-emitting display device capable of increasing the lifetime of the blue sub-pixel may be provided.

Further, according to the embodiments of the present disclosure, the organic light-emitting display device capable of reducing the lateral leakage current may be provided. In particular, the organic light-emitting display device capable of preventing the lateral leakage current of the blue sub-pixel from occurring may be provided.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 and FIG. 2 are plan and cross-sectional views showing an organic light-emitting display device according to one embodiment of the present disclosure, respectively.

FIG. 3 is a cross-sectional view showing an organic light-emitting display device according to one embodiment of the present disclosure.

FIG. 4 and FIG. 5 are plan and cross-sectional views showing an organic light-emitting display device according to one embodiment of the present disclosure, respectively.

FIG. 6 to FIG. 17 are diagrams for illustrating a method for manufacturing an organic light-emitting display device according to one embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure and the appended claims.

A shape, a size, a ratio, an angle, a number, etc., disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which the embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments.” “examples,” “aspects,” and the like should not be construed such that any aspect or design as described is beneficial or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, organic light-emitting display devices according to embodiments according to the present disclosure will be described in detail with reference to the accompanying drawings.

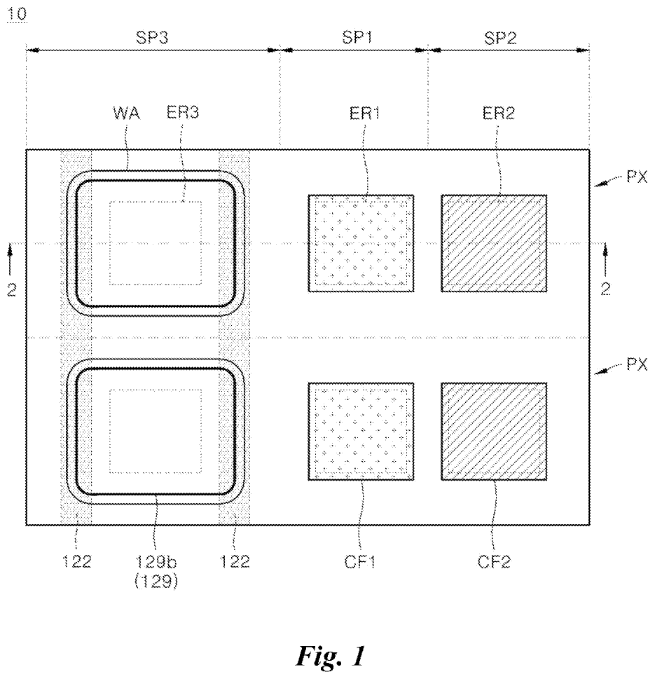

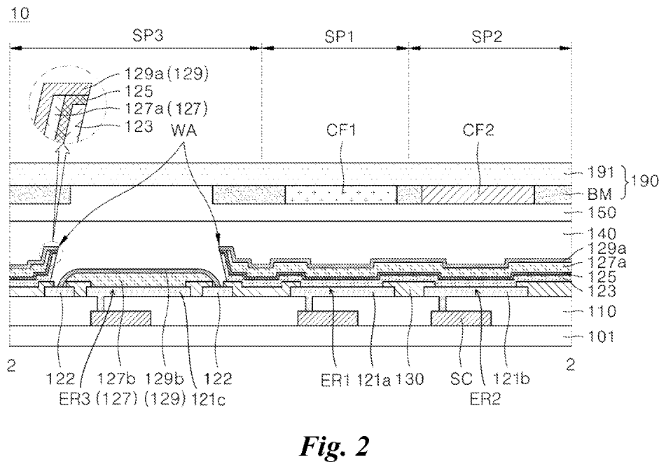

FIG. 1 and FIG. 2 are plan and cross-sectional views showing an organic light-emitting display device according to an embodiment of the present disclosure, respectively.

Referring to FIG. 1 and FIG. 2, an organic light-emitting display device 10 according to one embodiment of the present disclosure may include a plurality of pixels PX in a display area. Each pixel PX may include a plurality of sub-pixels. In this embodiment, each pixel PX includes three sub-pixels, for example, a first sub-pixel SP1, a second sub-pixel SP2, and a third sub-pixel SP3. the first sub-pixel SP1 includes a first light-emitting area ER1, the second sub-pixel SP2 includes a second light-emitting area ER2, and the third sub-pixel SP3 includes a third light-emitting area ER3. For example, the first sub-pixel SP1 may be a red sub-pixel, the second sub-pixel SP2 may be a green sub-pixel, and the third sub-pixel SP3 may be a blue sub-pixel. A position of the third sub-pixel SP3 is not limited to that as shown in FIG. 1 and FIG. 2. The third sub-pixel SP3 may be positioned at a right side, or may be positioned at a center, e.g., between the first sub-pixel SP1 and the second sub-pixel SP2.

The organic light-emitting display device according to one embodiment of the present disclosure includes a substrate 101, a sub-pixel driver circuit SC, first, second and third anode electrodes 121a, 121b, and 121c, ground electrodes 122, a first organic light-emitting layer 123, a first cathode electrode 125, a second organic light-emitting layer 127, a second cathode electrode 129, a bank 130, a wall structure WA, and first and second color filters CF1 and CF2.

The sub-pixel driver circuit SC including driving thin-film transistor may be disposed on the substrate 101 and in each sub-pixel. The substrate 101 may be made of a flexible material. The substrate 101 may be made of plastic or thin glass, for example. A light blocking layer may be disposed under the driving thin-film transistor and on the substrate 101 to block external light from being introduced into the driving thin-film transistor through the substrate 101. A buffer layer covering the light blocking layer may be disposed on the substrate 101. The buffer layer may be embodied as an inorganic insulating film, an organic insulating film, or an inorganic and organic composite insulating film, and may be formed in a single layer or multilayer structure.

An insulating layer 110 covering the sub-pixel driver circuit SC may be disposed on the substrate 101. The insulating layer 110 may be embodied as an inorganic insulating film, an organic insulating film, or an inorganic and organic composite insulating film, and may be formed in a single layer or multilayer structure.

On the insulating layer 110, the first to third anode electrodes 121a, 121b, and 121c and the ground electrode 122 may be disposed. Each anode electrode may extend through the insulating layer 110 so as to be connected to each sub-pixel driver circuit SC. A pair of ground electrodes 122 spaced apart from the third anode electrode 121c may be disposed on the insulating layer 110 and in the third sub-pixel SP3. The pair of ground electrodes 122 may be respectively disposed on both opposing sides of the third anode electrode 121c. In one embodiment, a single ground electrode 122 may be disposed on one side of the third anode electrode 121c instead of two ground electrodes 122 on either side of the third anode electrode 121c.

The organic light-emitting display device according to one embodiment of the present disclosure may be embodied as an organic light-emitting display device in a top emission scheme in which light emitted from the organic light-emitting layer travels through the cathode electrode and is directed toward a top surface of the organic light-emitting display device. Each of the first, second and third anode electrodes 121a, 121b, and 121c may include a metal material with high reflectance and, for example, may include aluminum (Al), a stack structure of aluminum and titanium layers (Ti/Al/Ti), a stack structure of aluminum and ITO layers (ITO/Al/ITO), an APC alloy, or a stack structure of APC alloy and ITO layers (ITO/APC/ITO). In this regard, the APC alloy is an alloy of silver (Ag), palladium (Pd), and copper (Cu).

The bank 130 covering edges of the first, second and third anode electrodes 121a, 121b, and 121c and an edge of the ground electrode 122 may be disposed on the insulating layer 110. The bank 130 defines (e.g., has respective openings exposing) the light-emitting area of each sub-pixel, and may define (e.g., have an opening exposing) a contact area of the ground electrode 122. The contact area of the ground electrode 122 refers to a portion of the ground electrode 122 that is not covered with the bank 130. Since an area where the bank 130 is formed and an area where the ground electrode 122 is disposed do not emit light, each thereof may be referred to as a non-light-emitting area. The bank 130 may be embodied as an organic insulating film made of, for example, acryl resin, epoxy resin, phenolic resin, polyamide resin, or polyimide resin.

The first organic light-emitting layer 123 and the first cathode electrode 125 may be sequentially stacked in the first and second light-emitting areas ER1 and ER2 of the first and second sub-pixels SP1 and SP2. The first organic light-emitting layer 123 and the first cathode electrode 125 may extend continuously across the first and second sub-pixels SP1 and SP2. The first organic light-emitting layer 123 and the first cathode electrode 125 may extend to a peripheral area of the third sub-pixel SP3 to be included in the wall structure WA. The term “cathode electrode” includes the meaning of a layer, and the first cathode electrode 125 may be referred to as the first cathode electrode layer 125.

The first cathode electrode 125 may be a common electrode commonly connected to organic light-emitting elements respectively disposed in the first sub-pixel SP1 and the second sub-pixel SP2. The first cathode electrode 125 may be connected to a ground line or a low-potential line of the organic light-emitting display device.

The first organic light-emitting layer 123 may include a structure in which a hole injection layer, a hole transport layer, a light-emitting layer, an electron transport layer, and an electron injection layer are stacked. The first organic light-emitting layer 123 may further include an electron blocking layer between the hole transport layer and the light-emitting layer, and further include a hole blocking layer between the light-emitting layer and the electron transport layer. The light-emitting layer of the first organic light-emitting layer 123 may include a yellow light-emitting layer and a green light-emitting layer. Alternatively, the light-emitting layer of the first organic light-emitting layer 123 may be a light-emitting layer in which a single host material is doped with a yellow dopant and a green dopant. The light-emitting layer of the first organic light-emitting layer 123 may include a red light-emitting layer and a green light-emitting layer. Alternatively, the light-emitting layer of the first organic light-emitting layer 123 may be a light-emitting layer in which a single host material is doped with a red dopant and a green dopant.

The organic light-emitting display device according to one embodiment of the present disclosure may be embodied as an organic light-emitting display device in a top emission scheme in which light emitted from the organic light-emitting layer travels through the cathode electrode and is directed toward a top surface of the organic light-emitting display device. The first cathode electrode 125 may be made of a transparent conductive material. The first cathode electrode 125 may be made of a transparent conductive oxide such as, for example, indium-tin-oxide (ITO), or indium-zinc-oxide (IZO).

Further, the second organic light-emitting layer 127 and the second cathode electrode 129 may be disposed in the first, second and third sub-pixels SP1, SP2, and SP3. Each of the second organic light-emitting layer 127 and the second cathode electrode 129 may be broken or discontinuous at the peripheral area of the third sub-pixel SP3. The term “cathode electrode” includes the meaning of a layer, and the second cathode electrode 129 may be referred to as the second cathode electrode layer 129.

The second organic light-emitting layer 127 may include a structure in which a hole injection layer, a hole transport layer, a light-emitting layer, an electron transport layer, and an electron injection layer are stacked. The second organic light-emitting layer 127 may further include an electron blocking layer between the hole transport layer and the light-emitting layer, and further include a hole blocking layer between the light-emitting layer and the electron transport layer. The light-emitting layer of the second organic light-emitting layer 127 may include a blue light-emitting layer. The light-emitting layer of the second organic light-emitting layer 127 may be a light-emitting layer in which a single host material is doped with a blue dopant.

The second cathode electrode 129 may be made of a transparent conductive material. The second cathode electrode 129 may be made of a transparent conductive oxide such as, for example, indium-tin-oxide (ITO), or indium-zinc-oxide (IZO).

The second organic light-emitting layer 127 may include a first portion 127a of the second organic light-emitting layer 127 which is disposed in the first sub-pixel SP1 and the second sub-pixel SP2 and is disposed in the peripheral area of the third sub-pixel SP3, and a second portion 127b of the second organic light-emitting layer 127 disposed in an inner area of the third sub-pixel SP3 so as to cover the third anode electrode 121c and a partial area of the ground electrode 122. In one embodiment, an edge of the second portion 127b of the second organic light-emitting layer 127 may not cover the ground electrode 122 but may cover at least a portion of the bank 130 disposed between the third anode electrode 121c and the ground electrode 122. The first portion 127a of the second organic light-emitting layer 127 and the second portion 127b of the second organic light-emitting layer 127 may not be connected to each other. The first portion 127a of the second organic light-emitting layer 127 disposed in the peripheral area of the third sub-pixel SP3 may be included in the wall structure WA.

The second cathode electrode 129 may include a first portion 129a of the second cathode electrode 129 disposed in the first sub-pixel SP1 and the second sub-pixel SP2, and disposed in the peripheral area of the third sub-pixel SP3, and a second portion 129b of the second cathode electrode 129 disposed in the inner area of the third sub-pixel SP3 so as to cover the second portion 127b of the second organic light-emitting layer 127. The first portion 129a of the second cathode electrode 129 and the second portion 129b of the second cathode electrode 129 may not be connected to each other. A portion of the first portion 129a of the second cathode electrode 129 disposed in the peripheral area of the third sub-pixel SP3 may be included in the wall structure WA. At least a portion of the second portion 129b of the second cathode electrode 129 may contact the ground electrodes 122. Two opposing edges of the second portion 129b of the second cathode electrode 129 may respectively contact the pair of ground electrodes 122.

In the third sub-pixel SP3, the second portion 129b of the second cathode electrode 129, the second portion 127b of the second organic light-emitting layer 127, and the third anode electrode 121c constitute or are included in a blue organic light-emitting element. Since the second portion 129b of the second cathode electrode 129 covers an entirety of the second portion 127b of the second organic light-emitting layer 127 in the third sub-pixel SP3, the second portion 127b of the second organic light-emitting layer 127 may be protected from moisture and outgassing. Therefore, a lifetime of the blue organic light-emitting element disposed in the third sub-pixel SP3 may be increased. Further, in the third sub-pixel SP3, a stack of the second portion 129b of the second cathode electrode 129 and the second portion 127b of the second organic light-emitting layer 127 is formed in an island-shaped isolated structure surrounded with the wall structure WA. Thus, the lateral leakage current of the blue organic light-emitting element disposed in the third sub-pixel SP3 may be prevented. It should be understood that “surrounded” includes the broad meaning of being surrounded in only one, two or all three planes. For example, the wall structure WA may surround the stack of the second portion 129b of the second cathode electrode 129 and the second portion 127b of the second organic light-emitting layer 127 on fewer than six sides, such as on four sides (e.g., left, right, front and back) without being surrounded on top and bottom sides.

The wall structure WA may include a portion of the first organic light-emitting layer 123, a portion of the first cathode electrode 125, a portion of the second organic light-emitting layer 127, and a portion of the second cathode electrode 129. The wall structure WA may be formed in a rectangular ring shape surrounding the third light-emitting area ER3. The wall structure WA may be formed in a rectangular ring shape surrounding the second portion 129b of the second cathode electrode 129. The wall structure WA may be formed in a form of a rectangular ring with rounded corners. The wall structure WA may be inclined toward the inside of the third sub-pixel SP3. The wall structure WA may protrude upwardly beyond the second portion 129b of the second cathode electrode 129. A vertical level of the upper end of the wall structure WA may be higher than that of the second portion 129b of the second cathode electrode 129. In a plan view, the upper end of the wall structure WA may overlap the ground electrode 122. In the plan view, the upper end of the wall structure WA may overlap (e.g., partially overlap) the opening in the bank 130 that exposes the ground electrode 122.

The first portion 129a of the second cathode electrode 129 may contact the first cathode electrode 125 at the upper end of the wall structure WA. Each of the first portion 129a of the second cathode electrode 129 and the first cathode electrode 125 may be connected to a ground line or a low-potential line of the organic light-emitting display device. The first portion 129a of the second cathode electrode 129 and the first cathode electrode 125 have an equal electrical potential. Thus, in the first sub-pixel SP1 and the second sub-pixel SP2, the second organic light-emitting layer 127 disposed between the first portion 129a of the second cathode electrode 129 and the first cathode electrode 125 does not emit light. In the first sub-pixel SP1 and the second sub-pixel SP2, the first portion 129a of the second cathode electrode 129 and the first cathode electrode 125 are electrically connected to each other and act as one cathode electrode. Thus, electrical resistance of the cathode electrode may be reduced in the first sub-pixel SP1 and the second sub-pixel SP2. Thus, the organic light-emitting display device may operate at a reduced power level.

The second organic light-emitting layer 127 may include a structure in which a hole injection layer, a hole transport layer, a light-emitting layer, an electron transport layer, and an electron injection layer are stacked. The second organic light-emitting layer 127 may further include an electron blocking layer between the hole transport layer and the light-emitting layer, and further include a hole blocking layer between the light-emitting layer and the electron transport layer. The light-emitting layer of the second organic light-emitting layer 127 may include a blue light-emitting layer. The light-emitting layer of the second organic light-emitting layer 127 may be a light-emitting layer in which a single host material is doped with a blue dopant.

The second cathode electrode 129 may be made of a transparent conductive material. The second cathode electrode 129 may be made of a transparent conductive oxide such as, for example, indium-tin-oxide (ITO), or indium-zinc-oxide (IZO).

The organic light-emitting display device 10 according to one embodiment of the present disclosure may include an encapsulation layer 140 covering the second cathode electrode 129 and a color filter substrate 190 disposed on the encapsulation layer 140.

The encapsulation layer 140 may include an inorganic insulating layer, an organic insulating layer, or a stack structure thereof. The encapsulation layer 140 may have a three-layer structure including, for example, an inorganic insulating layer/organic insulating layer/inorganic insulating layer. The encapsulation layer 140 serves to prevent moisture, oxygen, or particles from invading the organic light-emitting display device.

The color filter substrate 190 may be attached to the encapsulation layer 140 via an adhesive layer 150. The color filter substrate 190 may include a protective substrate 191, a first color filter CF1 and a second color filter CF2 disposed on the lower surface of the protective substrate 191, and a black matrix BM disposed on the lower surface of the protective substrate 191 along edges of the first color filter CF1 and the second color filter CF2. The first color filter CF1 may be disposed in the first sub-pixel SP1, and the second color filter CF2 may be disposed in the second sub-pixel SP2. A color filter may not be disposed in the third sub-pixel SP3. As such, the adhesive layer 150 may have a protrusion that is in direct contact with the protective substrate 191 in the third sub-pixel SP3 due to absence of any color filter in the third sub-pixel SP3. Thickness of the adhesive in the third sub-pixel SP3 may exceed that in the first and second sub-pixels SP1, SP2. The first color filter CF1 may be a red color filter, and the second color filter CF2 may be a green color filter. In one embodiment, the first color filter CF1, the second color filter CF2, and the black matrix BM disposed one the side end thereof may be directly disposed on the encapsulation layer 140. The protective substrate 191 may be disposed covering the first color filter CF1, the second color filter CF2, and the black matrix BM.

Therefore, in the third sub-pixel SP3 as the blue sub-pixel, the blue light is emitted from the second organic light-emitting layer 127 itself. Thus, a separate color filter is not disposed in the third sub-pixel SP3. Thus, the luminance of the blue organic light-emitting element disposed in the third sub-pixel SP3 may be improved, such that power consumption of the blue organic light-emitting element may be reduced and the lifespan of the blue organic light-emitting element may be increased. This may improve the power consumption of the display device and may increase the lifespan of the display device.

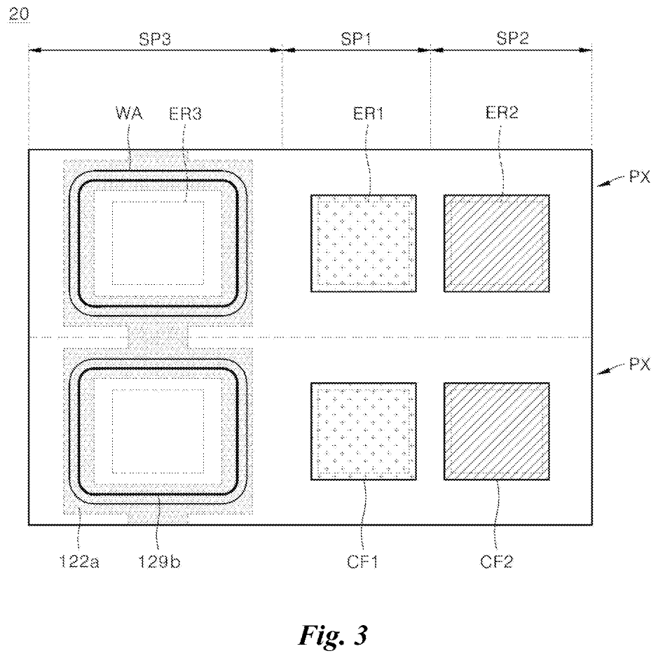

FIG. 3 is a cross-sectional view showing an organic light-emitting display device 20 according to one embodiment of the present disclosure.

Referring to FIG. 3, the organic light-emitting display device 20 according to one embodiment of the present disclosure is different from the organic light-emitting display device 10 in that a structure of a ground electrode 122a thereof is different from that of the ground electrode 122.

The ground electrode 122a may be formed in a shape of a rectangular ring and may be disposed in the third sub-pixel SP3. The ground electrode 122a may be formed in the shape of the rectangular ring with rounded corners and may be disposed in the third sub-pixel SP3.

Four sides of the second portion 129b of the second cathode electrode 129 may contact the ground electrode 122a. Accordingly, a contact area between the second portion 129b of the second cathode electrode 129 and the ground electrode 122a may be increased, and thus, stable contact therebetween may be ensured.

Further, the ground electrodes 122a respectively disposed in the third sub-pixels SP3 adjacent to each other may be connected to each other via a connection portion. A position of the connection portion is not limited to that shown in FIG. 3.

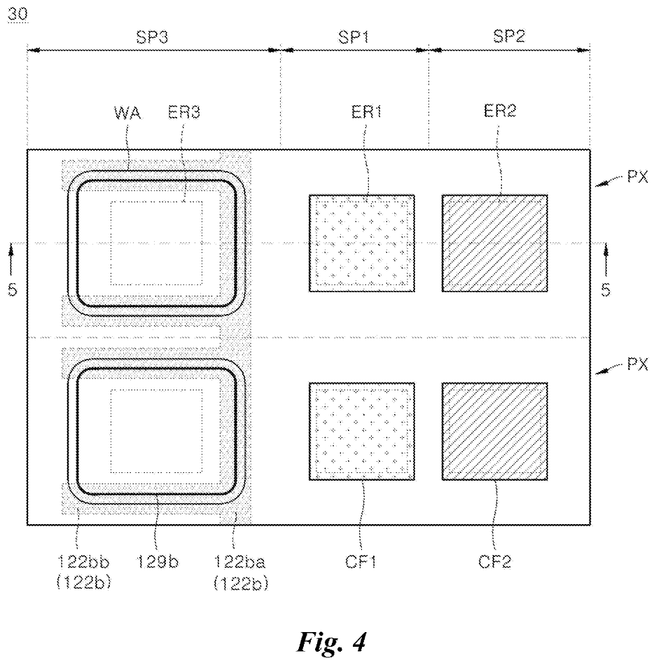

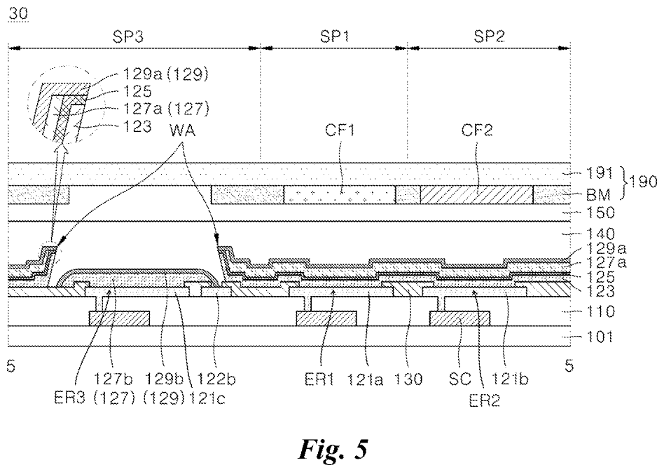

FIGS. 4 and 5 are plan and cross-sectional views showing an organic light-emitting display device 30 according to one embodiment of the present disclosure, respectively.

Referring to FIG. 4 and FIG. 5, the organic light-emitting display device 30 according to one embodiment of the present disclosure is different from the organic light-emitting display device 10 in that a structure of a ground electrode 122b thereof is different from that of the ground electrode 122.

The ground electrode 122b has a first extension 122ba extending in a first direction, and a pair of second extensions 122bb branching from the first extension 122ba and extending in a second direction transverse the first direction, wherein the pair of second extensions 122bb are spaced apart from each other. Three sides of the second portion 129b of the second cathode electrode 129 may contact the ground electrode 122b. Accordingly, a contact area between the second portion 129b of the second cathode electrode 129 and the ground electrode 122b may be increased, and the stable contact therebetween may be ensured. A position of the first extension 122ba is not limited to that as shown in FIG. 4 and FIG. 5. For example, the first extension 122ba is depicted as being between the first and third emission regions ER3. In some embodiments, the first extension 122ba is between the third emission region ER3 and a second emission region ER2 of a neighboring pixel PX.

Hereinafter, a method for manufacturing an organic light-emitting display device according to one embodiment of the present disclosure will be described with reference to the drawings.

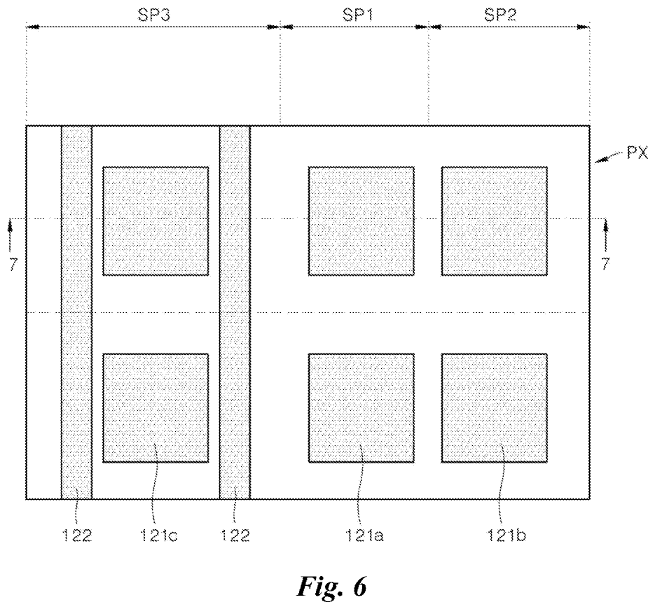

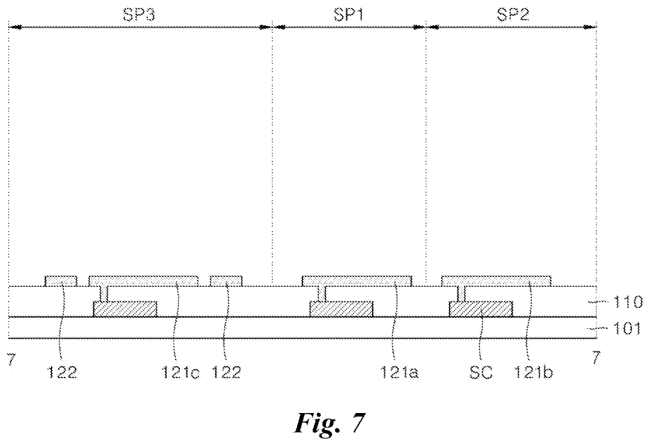

FIG. 6 to FIG. 17 are diagrams for illustrating a method for manufacturing the organic light-emitting display device 10 according to one embodiment of the present disclosure as shown in FIGS. 1 and 2. FIGS. 6, 8, 10, 12, 14 and 16 are plan views for illustrating the method for manufacturing the organic light-emitting display device 10 according to one embodiment of the present disclosure. FIGS. 7, 9, 11, 13, 15 and 17 are cross-sectional views illustrating the method for manufacturing the organic light-emitting display device 10 according to one embodiment of the present disclosure.

Referring to FIGS. 6 and 7, the sub-pixel driver circuits SC including the thin-film transistors may be formed on the substrate 101. The substrate 101 may be made of a flexible material. The substrate 101 may be made of plastic or thin glass, for example.

The insulating layer 110 covering the sub-pixel driver circuits SC may be formed on the substrate 101. The insulating layer 110 may be embodied as an inorganic insulating film, an organic insulating film, or an inorganic and organic composite insulating film, and may be formed in a single layer or multilayer structure.

Then, an electrode material is applied thereon, and patterning process, which may include a photolithography process and an etching process, is performed thereon. Thus, the first, second and third anode electrodes 121a, 121b, and 121c and the ground electrodes 122 may be formed on the insulating layer 110. Each of the first, second and third anode electrodes 121a, 121b, and 121c may extend through the insulating layer 110 so as to be connected to each sub-pixel driver circuit SC. Then, the pair of ground electrodes 122 spaced apart from the third anode electrode 121c may be disposed on the insulating layer 110 and in the third sub-pixel SP3. The pair of ground electrodes 122 may be respectively disposed on both opposing sides of the third anode electrode 121c. The first, second and third anode electrodes 121a, 121b, and 121c and the ground electrode 122 may be simultaneously formed in the same process. Each of the first, second and third anode electrodes 121a, 121b, and 121c and the ground electrode 122 may include a metal material with high reflectance and, for example, may include aluminum (Al), a stack structure of aluminum and titanium layers (Ti/Al/Ti), a stack structure of aluminum and ITO layers (ITO/Al/ITO), an APC alloy, or a stack structure of APC alloy and ITO layers (ITO/APC/ITO). In this regard, the APC alloy is an alloy of silver (Ag), palladium (Pd), and copper (Cu).

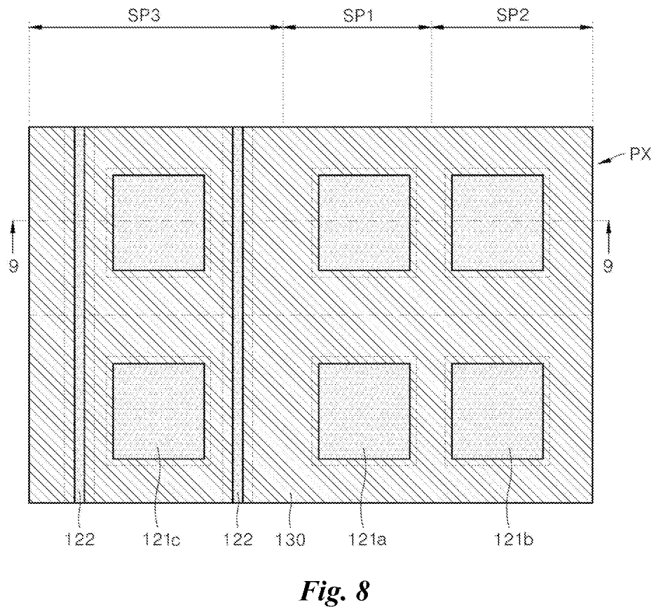

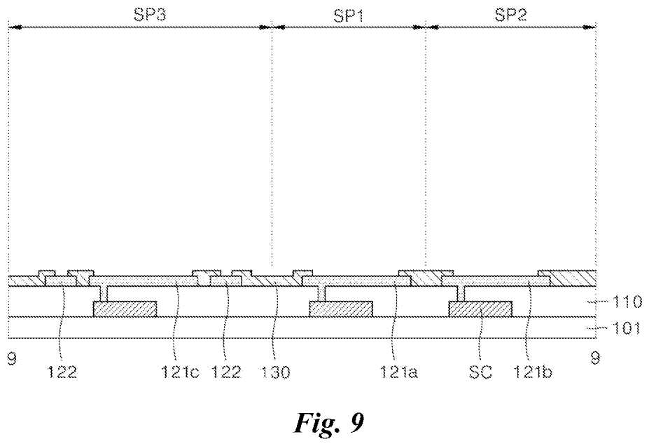

Referring to FIG. 8 and FIG. 9, the bank material is applied thereon, and a patterning process, which may include a photolithography process and an etching process, is performed thereon. Thus, the bank 130 covering edges of the first, second and third anode electrodes 121a, 121b, and 121c and an edge of the ground electrode 122 may be disposed on the insulating layer 110. The bank 130 defines the light-emitting area of each sub-pixel, and may define a contact area of the ground electrode 122. The contact area of the ground electrode 122 refers to a portion of the ground electrode 122 that is not covered with the bank 130. Since an area where the bank 130 is formed and an area where the ground electrode 122 is disposed do not emit light, each thereof may be referred to as a non-light-emitting area. The bank 130 may be embodied as an organic insulating film made of, for example, acryl resin, epoxy resin, phenolic resin, polyamide resin, or polyimide resin.

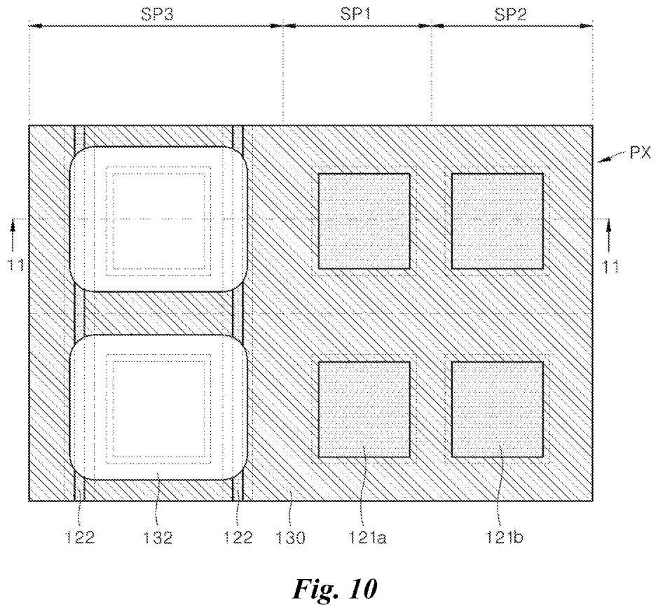

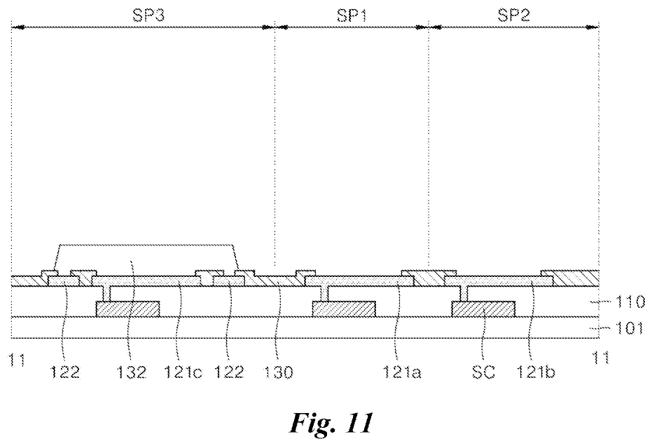

Referring to FIG. 10 and FIG. 11, a shield layer material is applied thereon, and a

patterning process, which may include a photolithography process and an etching process, is performed thereon. Thus, a shield layer or mask layer 132 may be formed on the third anode electrode 121c and the ground electrode 122 and in the third sub-pixel SP3. The shield layer 132 may cover a portion of each of the third anode electrode 121c and the ground electrode 122 that are not covered with (e.g., are exposed by) the bank 130. The shield layer 132 may cover the bank 130 between the third anode electrode 121c and the ground electrode 122. The shield layer 132 may be formed in a form of an island and may be disposed in the third sub-pixel SP3. The shield layer 132 may have a rectangular shape in a plan view. The shield layer 132 may have a rectangular shape with rounded corners in a plan view. The shield layer 132 may have a shape in which a width thereof decreases as the shield layer extends toward a top thereof in a cross-sectional view. Thus, a width of an upper surface (e.g., a surface distal the substrate 101) of the shield layer 132 may be smaller than a width of a lower surface (e.g., a surface proximal the substrate 101) thereof. The width of the upper surface of the shield layer 132 may be larger than an inner spacing between the ground electrodes 122 and may be smaller than an outer spacing between the ground electrodes 122. The inner spacing between the ground electrodes 122 means a spacing between inner side surfaces of the ground electrodes 122 facing each other. The outer spacing between the ground electrodes 122 means a spacing between outer side surfaces of the ground electrodes 122. A side edge of the upper surface of the shield layer 132 overlaps a portion of the ground electrode 122 that is not covered with the bank 130 in some embodiments.

The shield layer 132 may be made of, for example, a fluorine-based polymer or a fluoropolymer having a carbon backbone in which carbon-carbon bonds constitute a chain structure and containing a large amount of fluorine (F).

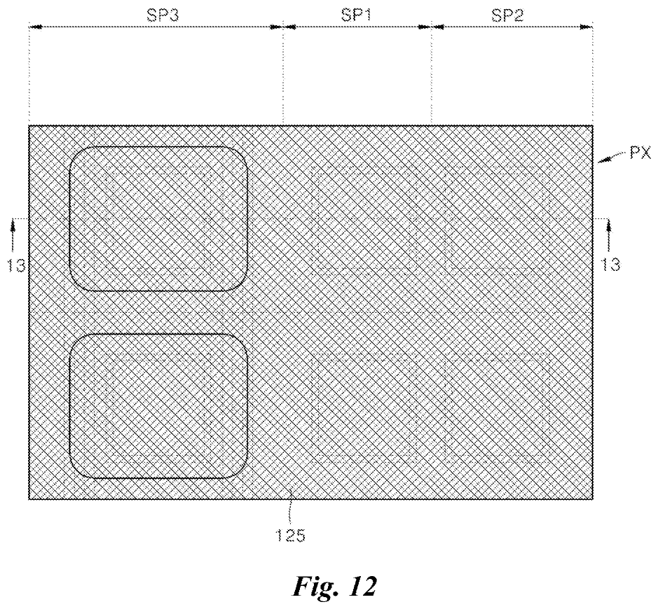

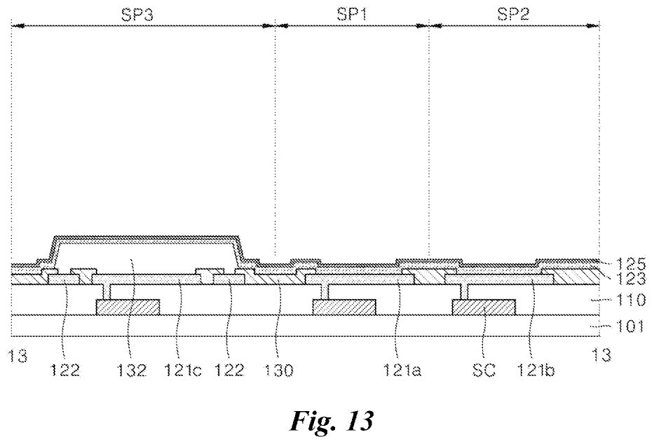

Referring to FIG. 12 and FIG. 13, the first organic light-emitting layer 123 and the first cathode electrode 125 may be sequentially formed on the shield layer 132, the second anode electrode 121b, the third anode electrode 121c, and the bank 130.

The first organic light-emitting layer 123 and the first cathode electrode 125 may extend continuously across the first, second and third sub-pixels SP1, SP2, and SP3. The first cathode electrode 125 may be a common electrode commonly connected to the organic light-emitting elements respectively disposed in the first sub-pixel SP1 and the second sub-pixel SP2. The first cathode electrode 125 may be connected to the ground line of the display device.

The first organic light-emitting layer 123 may include a structure in which a hole injection layer, a hole transport layer, a light-emitting layer, an electron transport layer, and an electron injection layer are stacked. The first organic light-emitting layer 123 may further include an electron blocking layer between the hole transport layer and the light-emitting layer, and further include a hole blocking layer between the light-emitting layer and the electron transport layer. The light-emitting layer of the first organic light-emitting layer 123 may include a yellow light-emitting layer and a green light-emitting layer. Alternatively, the light-emitting layer of the first organic light-emitting layer 123 may be a light-emitting layer in which a yellow dopant and a green dopant are doped into a single host material. The light-emitting layer of the first organic light-emitting layer 123 may include a red light-emitting layer and a green light-emitting layer. Alternatively, the light-emitting layer of the first organic light-emitting layer 123 may be a light-emitting layer in which a single host material is doped with a red dopant and a green dopant.

The first cathode electrode 125 may be made of a transparent conductive material. The first cathode electrode 125 may be made of a transparent conductive oxide such as, for example, indium-tin-oxide (ITO), or indium-zinc-oxide (IZO).

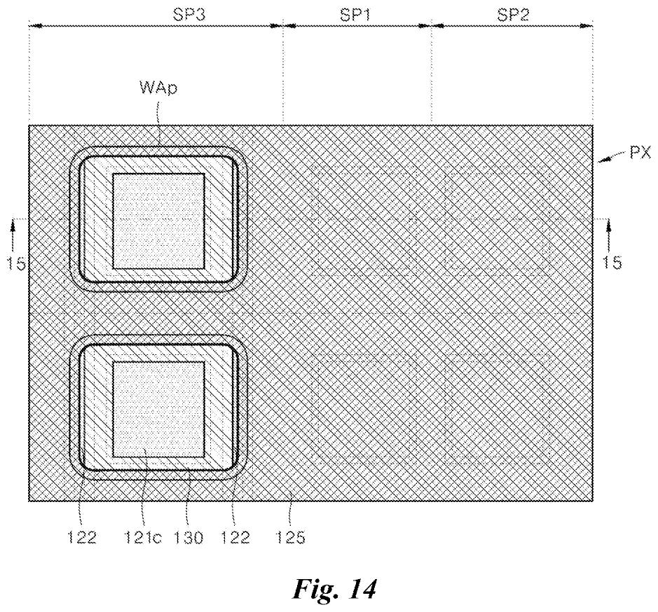

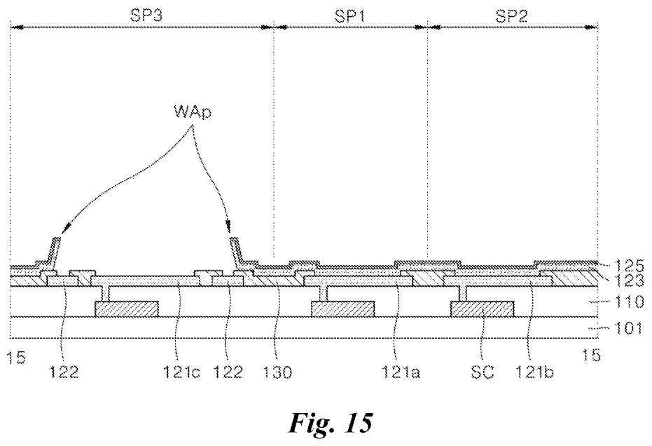

Referring to FIG. 14 and FIG. 15, the shield layer 132 may be removed in a lift-off process. The lift-off process may be, for example, a wet etching process using a fluorine (F)-based organic solvent. When the shield layer 132 is removed, the first organic light-emitting layer 123 and the first cathode electrode 125 disposed on an upper surface of the shield layer 132 may be removed together. The shield layer 132 has been removed such that the third anode electrode 121c and the ground electrodes 122 may be exposed in the third sub-pixel SP3.

However, portions of the first organic light-emitting layer 123 and the first cathode electrode 125 disposed on side surfaces of the shield layer 132 remain as a pre-wall structure WAp. The pre-wall structure WAp may be formed in a rectangular ring shape surrounding the third anode electrode 121c. The pre-wall structure WAp may be formed in the form of the rectangular ring with rounded corners. The pre-wall structure WAp may be inclined toward the inside of the third sub-pixel SP3. An upper end of the pre-wall structure WAp may overlap the ground electrode 122.

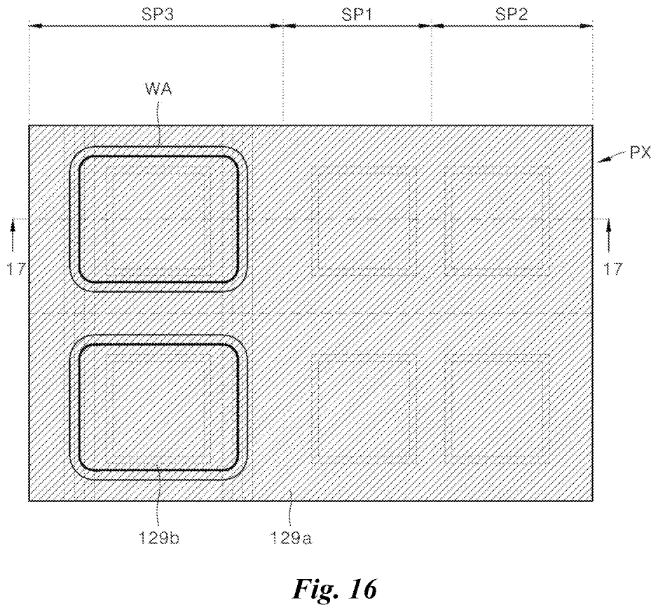

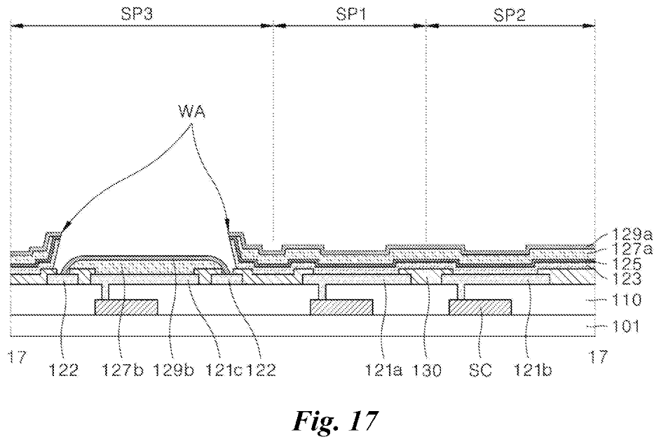

Referring to FIGS. 16 and 17, the second organic light-emitting layer 127 and the second cathode electrode 129 may be formed on the third anode electrode 121c, the ground electrodes 122, and the first cathode electrode 125.

The second organic light-emitting layer 127 and the second cathode electrode 129 may be disposed in the first, second and third sub-pixel SP1, SP2, and SP3. Each of the second organic light-emitting layer 127 and the second cathode electrode 129 may be broken or discontinuous at the peripheral area of the third sub-pixel SP3.

The second organic light-emitting layer 127 may include the first portion 127a of the second organic light-emitting layer 127 which is disposed in the first sub-pixel SP1 and the second sub-pixel SP2 and is disposed in the peripheral area of the third sub-pixel SP3, and the second portion 127b of the second organic light-emitting layer 127 disposed in an inner area of the third sub-pixel SP3 so as to cover the third anode electrode 121c and a partial area of the ground electrode 122. In one embodiment, an edge of the second portion 127b of the second organic light-emitting layer 127 may not cover the ground electrode 122 but may cover at least a portion of the bank 130 disposed between the third anode electrode 121c and the ground electrode 122. The first portion 127a of the second organic light-emitting layer 127 and the second portion 127b of the second organic light-emitting layer 127 may not be connected to each other.

The second cathode electrode 129 may include the first portion 129a of the second cathode electrode 129 disposed in the first sub-pixel SP1 and the second sub-pixel SP2, and disposed in the peripheral area of the third sub-pixel SP3, and the second portion 129b of the second cathode electrode 129 disposed in the inner area of the third sub-pixel SP3 so as to cover the second portion 127b of the second organic light-emitting layer 127. The first portion 129a of the second cathode electrode 129 and the second portion 129b of the second cathode electrode 129 may not be connected to each other. A portion of the first portion 129a of the second cathode electrode 129 disposed in the peripheral area of the third sub-pixel SP3 may constitute the wall structure WA. At least a portion of the second portion 129b of the second cathode electrode 129 may contact the ground electrodes 122. Two opposing edges of the second portion 129b of the second cathode electrode 129 may respectively contact the pair of ground electrodes 122.

Thus, a portion of the second organic light-emitting layer 127 and a portion of the second cathode electrode 129 are additionally formed on the pre-wall structure WAp, resulting in the wall structure WA. The wall structure WA may be formed in the rectangular ring shape surrounding the second portion 129b of the second cathode electrode 129. The wall structure WA may be formed in the form of a rectangular ring with rounded corners. The wall structure WA may be inclined toward the inside of the third sub-pixel SP3. A vertical level of the upper end of the wall structure WA may be higher than that of the second portion 129b of the second cathode electrode 129. In a plan view, the upper end of the wall structure WA may overlap the ground electrode 122.

The first portion 129a of the second cathode electrode 129 may contact the first cathode electrode 125 at the upper end of the wall structure WA. Each of the first portion 129a and the second portion 129b of the second cathode electrode 129 may be connected to the ground line of the display device.

The second organic light-emitting layer 127 may include a structure in which a hole injection layer, a hole transport layer, a light-emitting layer, an electron transport layer, and an electron injection layer are stacked. The second organic light-emitting layer 127 may further include an electron blocking layer between the hole transport layer and the light-emitting layer, and further include a hole blocking layer between the light-emitting layer and the electron transport layer. The light-emitting layer of the second organic light-emitting layer 127 may include a blue light-emitting layer. The light-emitting layer of the second organic light-emitting layer 127 may be a light-emitting layer in which a single host material is doped with a blue dopant.

The second cathode electrode 129 may be made of a transparent conductive material. The second cathode electrode 129 may be made of a transparent conductive oxide such as, for example, indium-tin-oxide (ITO), or indium-zinc-oxide (IZO).

Referring back to FIGS. 1 and 2, the encapsulation layer 140 covering the second cathode electrode 129 may be formed on the substrate 101. The encapsulation layer 140 may include an inorganic insulating layer, an organic insulating layer, or a stack structure thereof. The encapsulation layer 140 may have a three-layer structure including, for example, an inorganic insulating layer/organic insulating layer/inorganic insulating layer. The encapsulation layer 140 serves to prevent moisture, oxygen, or particles from invading the organic light-emitting display device.

Then, the color filter substrate 190 may be attached to the encapsulation layer 140 by the adhesive layer 150. The color filter substrate 190 may include the protective substrate 191, the first color filter CF1 and the second color filter CF2 disposed on the lower surface of the protective substrate 191, and the black matrix BM disposed on the lower surface of the protective substrate 191 along edges of the first color filter CF1 and the second color filter CF2. The first color filter CF1 may be disposed in the first sub-pixel SP1, and the second color filter CF2 may be disposed in the second sub-pixel SP2. A color filter may not be disposed in the third sub-pixel SP3. The first color filter CF1 may be a red color filter, and the second color filter CF2 may be a green color filter. A color filter may not be disposed in the third sub-pixel SP3. In one embodiment, the first color filter CF1, the second color filter CF2, and the black matrix BM disposed one the side end thereof may be directly disposed on the encapsulation layer 140, and then, the protective substrate covering the first color filter CF1, the second color filter CF2, and the black matrix BM may be disposed.

An organic light-emitting display device according to embodiments of the present disclosure may be described as follows.

A first aspect of the present disclosure provides an organic light-emitting display device comprising: a first anode electrode disposed in a first sub-pixel; a second anode electrode disposed in a second sub-pixel; a third anode electrode disposed in a third sub-pixel; at least one ground electrode disposed in the third sub-pixel and spaced apart from the third anode electrode; a first organic light-emitting layer, a first cathode electrode, a first portion of a second organic light-emitting layer, and a first portion of a second cathode electrode sequentially stacked on the first anode electrode and the second anode electrode; and a second portion of the second organic light-emitting layer and a second portion of the second cathode electrode sequentially stacked on the third anode electrode, wherein at least a portion of a side edge of the second portion of the second cathode electrode contacts the at least one ground electrode.

In some implementations of the first aspect, the display device further comprises a wall structure disposed in the third sub-pixel so as to surround the side edge of the second portion of the second cathode electrode, wherein the wall structure protrudes upwardly beyond the second portion of the second cathode electrode.

In some implementations of the first aspect, the wall structure comprises a portion of the first organic light-emitting layer, a portion of the first cathode electrode, a portion of the first portion of the second organic light-emitting layer, and a portion of the first portion of the second cathode electrode.

In some implementations of the first aspect, the first portion and the second portion of the second cathode electrode are disconnected from each other with the wall structure as a boundary.

In some implementations of the first aspect, the first cathode electrode and the first portion of the second cathode electrode contact each other at an upper end of the wall structure.

In some implementations of the first aspect, at least a portion of the wall structure overlaps the ground electrode.

In some implementations of the first aspect, the at least one ground electrode includes a pair of ground electrodes spaced apart from each other and disposed in the third sub-pixel, wherein two opposing edges of the second portion of the second cathode electrode are in contact with the pair of ground electrodes, respectively.

In some implementations of the first aspect, the at least one ground electrode is formed in a rectangular ring shape and is disposed in the third sub-pixel, wherein all of four side edges of the second portion of the second cathode electrode are in contact with the at least one ground electrode.

In some implementations of the first aspect, the at least one ground electrode includes: a first extension extending in a first direction; and a pair of second extensions extending from the first extension in a second direction transverse the first direction, wherein the pair of second extensions are spaced apart from each other and are disposed in the third sub-pixel, wherein three side edges of the second portion of the second cathode electrode contact the at least one ground electrode.

In some implementations of the first aspect, the first organic light-emitting layer includes a yellow light-emitting layer and a green light-emitting layer, wherein the second organic light-emitting layer includes a blue light-emitting layer.

In some implementations of the first aspect, the first organic light-emitting layer includes a red light-emitting layer and a green light-emitting layer, wherein the second organic light-emitting layer includes a blue light-emitting layer.

In some implementations of the first aspect, the display device further comprises: a red color filter disposed in the first sub-pixel; and a green color filter disposed in the second sub-pixel.

A second aspect of the present disclosure provides an organic light-emitting display device comprising: an anode electrode disposed in a sub-pixel; at least one ground electrode disposed in the sub-pixel and spaced apart from the anode electrode; an organic light-emitting layer and a cathode electrode sequentially stacked on the anode electrode; and a wall structure surrounding side edges of the cathode electrode and spaced apart from the side edges of the cathode electrode, wherein the wall structure includes a portion of the organic light-emitting layer and a portion of the cathode electrode, wherein at least a portion of side edges of the cathode electrode disposed on the anode electrode contacts the at least one ground electrode.

In some implementations of the second aspect, the organic light-emitting layer constituting the wall structure is a first organic light-emitting layer, and the cathode electrode constituting the wall structure is a first cathode electrode, wherein the wall structure further includes a portion of a second cathode electrode disposed under the first organic light-emitting layer, and a portion of a second organic light-emitting layer disposed under the second cathode electrode.

In some implementations of the second aspect, the first cathode electrode and the second cathode electrode contact each other at an upper end of the wall structure.

In some implementations of the second aspect, the first organic light-emitting layer is a blue light-emitting layer, and the second organic light-emitting layer includes a yellow light-emitting layer and a green light-emitting layer.

In some implementations of the second aspect, the first organic light-emitting layer is a blue light-emitting layer, and the second organic light-emitting layer includes a red light-emitting layer and a green light-emitting layer.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light-emitting display device, comprising:
a first anode electrode disposed in a first sub-pixel;
a second anode electrode disposed in a second sub-pixel;
a third anode electrode disposed in a third sub-pixel;
at least one ground electrode disposed in the third sub-pixel and spaced apart from the third anode electrode;
a first organic light-emitting layer, a first cathode electrode, a first portion of a second organic light-emitting layer, and a first portion of a second cathode electrode sequentially stacked on the first anode electrode and the second anode electrode; and
a second portion of the second organic light-emitting layer and a second portion of the second cathode electrode sequentially stacked on the third anode electrode,
wherein at least a portion of a side edge of the second portion of the second cathode electrode contacts the at least one ground electrode.

2. The organic light-emitting display device of claim 1, further comprising a wall structure disposed in the third sub-pixel and adjacent the side edge of the second portion of the second cathode electrode, wherein the wall structure protrudes upwardly beyond the second portion of the second cathode electrode.

3. The organic light-emitting display device of claim 2, wherein the wall structure comprises a portion of the first organic light-emitting layer, a portion of the first cathode electrode, a portion of the first portion of the second organic light-emitting layer, and a portion of the first portion of the second cathode electrode.

4. The organic light-emitting display device of claim 3, wherein the first portion and the second portion of the second cathode electrode are disconnected from each other with the wall structure as a boundary.

5. The organic light-emitting display device of claim 3, wherein the first cathode electrode and the first portion of the second cathode electrode contact each other at an upper end of the wall structure.

6. The organic light-emitting display device of claim 2, wherein at least a portion of the wall structure overlaps the at least one ground electrode.

7. The organic light-emitting display device of claim 1, wherein the at least one ground electrode includes a pair of ground electrodes spaced apart from each other and disposed in the third sub-pixel,
wherein two opposing edges of the second portion of the second cathode electrode are in contact with the pair of ground electrodes, respectively.

8. The organic light-emitting display device of claim 1, wherein the at least one ground electrode is formed in a rectangular ring shape and is disposed in the third sub-pixel,
wherein four side edges of the second portion of the second cathode electrode are in contact with the at least one ground electrode.

9. The organic light-emitting display device of claim 1, wherein the at least one ground electrode includes:
a first extension extending in a first direction; and
a pair of second extensions extending from the first extension in a second direction transverse the first direction, wherein the pair of second extensions are spaced apart from each other and are disposed in the third sub-pixel,
wherein three side edges of the second portion of the second cathode electrode contact the at least one ground electrode.

10. The organic light-emitting display device of claim 1, wherein the first organic light-emitting layer includes a yellow light-emitting layer and a green light-emitting layer, and the second organic light-emitting layer includes a blue light-emitting layer.

11. The organic light-emitting display device of claim 1, wherein the first organic light-emitting layer includes a red light-emitting layer and a green light-emitting layer, and the second organic light-emitting layer includes a blue light-emitting layer.

12. The organic light-emitting display device of claim 1, further comprising
a red color filter disposed in the first sub-pixel; and
a green color filter disposed in the second sub-pixel.

13. An organic light-emitting display device, comprising:
an anode electrode disposed in a sub-pixel;
at least one ground electrode disposed in the sub-pixel and spaced apart from the anode electrode;
an organic light-emitting layer and a cathode electrode sequentially stacked on the anode electrode, at least a portion of side edges of the cathode electrode disposed on the anode electrode contacting the at least one ground electrode; and
a wall structure adjacent the side edges of the cathode electrode and spaced apart from the side edges of the cathode electrode, the wall structure including:
a portion of the organic light-emitting layer; and
a portion of the cathode electrode.

14. The organic light-emitting display device of claim 13, wherein the organic light-emitting layer of the wall structure is a second organic light-emitting layer, and the cathode electrode of the wall structure is a second cathode electrode,
wherein the wall structure further includes a portion of a first cathode electrode disposed under the second organic light-emitting layer, and a portion of a first organic light-emitting layer disposed under the first cathode electrode.

15. The organic light-emitting display device of claim 14, wherein the first cathode electrode and the second cathode electrode contact each other at an upper end of the wall structure.

16. The organic light-emitting display device of claim 14, wherein the second organic light-emitting layer is a blue light-emitting layer, and the first organic light-emitting layer includes a yellow light-emitting layer and a green light-emitting layer.

17. The organic light-emitting display device of claim 14, wherein the second organic light-emitting layer is a blue light-emitting layer, and the first organic light-emitting layer includes a red light-emitting layer and a green light-emitting layer.

18. A method, comprising:
forming an anode electrode and a ground electrode on a substrate, the ground electrode being spaced apart from the anode electrode;
forming a bank that exposes a first surface of the anode electrode and a second surface of the ground electrode;
forming a shield layer that covers the anode electrode and the ground electrode;
forming a first light-emitting layer on the shield layer, the first light-emitting layer having a first portion on a sidewall of the shield layer;
forming a first cathode electrode layer on the first light-emitting layer, the first cathode electrode layer having a second portion on the sidewall of the shield layer;
forming a wall structure by removing the shield layer, the wall structure including the first portion and the second portion, the first surface and the second surface being exposed following the removing the shield layer;
forming a second light-emitting layer on the first surface and the wall structure, the second light-emitting layer being discontinuous between the first surface and the wall structure; and
forming a second cathode electrode layer on the second light-emitting layer, the second cathode electrode layer being discontinuous between the first surface and the wall structure, the second cathode electrode layer having at least one edge that is in contact with the second surface of the ground electrode.

19. The method of claim 18, wherein the forming a second light-emitting layer includes forming the second light-emitting layer that partially covers the second surface of the ground electrode.

20. The method of claim 18, further comprising:
forming an encapsulation layer on the second cathode electrode layer;
forming an adhesive layer on the encapsulation layer; and
attaching a color filter substrate to the adhesive layer, the color filter substrate including a protective substrate having a plurality of color filters thereon, the adhesive layer being in direct contact with the protective substrate over the anode electrode.
